(19) United States
(12) Patent Application Publication
(10) Pub. No.: US 2010/0270065 A1
(43) Pub. Date: Oct. 28, 2010

(54) Resin Composition For Printed Circuit Board and Printed Circuit Board Using The Same

(76) Inventors: Jae Choon Cho, Gyunggi-do (KR); Jun Rok Oh, Seoul (KR); Moon Soo Park, Gyunggi-do (KR); Sung Taek Lim, Gyunggi-do (KR); Hwa Young Lee, Gyunggi-do (KR)

Correspondence Address: BLAKELY SOKOLOFF TAYLOR & ZAFMAN LLP, 1279 OAKMEAD PARKWAY, SUNNYVALE, CA, 94085-4040, US

(21) Appl. No.: 12/507,627

(22) Filed: Jul. 22, 2009

(30) Foreign Application Priority Data
Apr. 23, 2009 (KR) 10-2009-0035541

(51) Int. Cl. H05K 1/03; C08L 63/00

(52) U.S. Cl. 174/258; 523/201

(57) ABSTRACT

Disclosed is a resin composition for a printed circuit board, which includes a complex epoxy resin including a bisphenol A epoxy resin obtained by dispersing silicone elastomer particles having a core-shell structure in a diglycidyl ether of bisphenol A epoxy resin, a cresol novolac epoxy resin, and a phosphorus-based epoxy resin; a bisphenol A curing agent; a curing accelerator; and an inorganic filler. A printed circuit board using the resin composition is also provided.

### CROSS REFERENCE TO RELATED APPLICATION

This application claims the benefit of Korean Patent Application No. 10-2009-0035541, filed on Apr. 23, 2009, entitled “Resin composition for printed circuit board and printed circuit board using the same”, which is hereby incorporated by reference in its entirety into this application.

### BACKGROUND OF THE INVENTION

1. Technical Field

The present invention relates to a resin composition for a printed circuit board (PCB) and a PCB using the same. More particularly, the present invention relates to a resin composition for a PCB, which includes a silicone elastomer having a core-shell structure, so that it can exhibit not only superior thermal stability and mechanical strength but also high toughness to thus result in a highly reliable substrate, upon application to an interlayer insulating layer of a multilayered PCB, and to a PCB using the same.

2. Description of the Related Art

In response to the trend of mobile phones becoming slimmer with increasing functionality and capacity thereof, a substrate for a mobile phone is required so that it is thin and contain a micro pattern and its inside is additionally imparted with various functions. Accordingly, in lieu of a conventional process of collectively laminating a copper foil and a prepreg using a V-press, a process including first laminating an insulating film and then forming a micro pattern is needed. Such a novel process would require the development of a new insulating material having a very high force of adhesion to a plating layer, different from conventional insulating material.

A build-up insulating material, conventionally developed, has a peel strength of about 0.5˜0.8 kN/m depending on desmearing conditions, and a build-up insulating material capable of stably exhibiting the strength of about 1.0 kN/m or more has not yet been commercialized. However, in order to manufacture a substrate for a mobile phone to be thin and impart a micro pattern in accordance with the trend of mobile phones becoming slimmer with increasing functionality and capacity thereof, urgently required is a build-up insulating material which can be applied to an outer layer of a substrate for a mobile phone and exhibit a peel strength of about 1.0 kN/m or more to ensure drop reliability equal to or higher than when using a conventional prepreg or RCC (resin coated copper).

### SUMMARY OF THE INVENTION

Accordingly, the present invention has been made keeping in mind the above problems encountered in the related art, and the present invention provides a resin composition for a PCB, in which silicone elastomer particles having a core-shell structure are introduced into an epoxy resin composition, thus increasing toughness, thereby preventing delamination or micro cracking upon reliability testing, in particular, thermal shock testing, and a PCB using the same.

Also, the present invention provides a resin composition for a build-up PCB, which exhibits superior thermal stability and mechanical strength and is able to show high peel strength even using a conventional substrate manufacturing process, and a PCB using the same.

Also, the present invention provides a resin composition for a PCB, which has high resistance to thermal shock, and a PCB using the same.

An aspect of the present invention provides a resin composition for a PCB, including (a) a complex epoxy resin including 20˜50 wt % of a bisphenol A epoxy resin obtained by dispersing silicone elastomer particles having a core-shell structure in a diglycidyl ether of bisphenol A (DGEBA) epoxy resin having an average epoxy resin equivalent of 200˜400, 20˜60 wt % of a cresol novolac epoxy resin having an average epoxy resin equivalent of 100˜300, and 20˜30 wt % of a phosphorus-based epoxy resin having an average epoxy resin equivalent of 400˜800, (b) a bisphenol A curing agent used in an equivalent ratio of 0.3˜1.5 with respect to a total epoxy group equivalent of the complex epoxy resin, (c) a curing accelerator used in an amount of 0.1˜1 part by weight based on 100 parts by weight of the complex epoxy resin and (d) an inorganic filler used in an amount of 10˜30 parts by weight based on 100 parts by weight of the complex epoxy resin.

In the resin composition, the silicone elastomer particles having the core-shell structure which are dispersed in the DGEBA epoxy resin may be used in an amount of 20˜60 wt %.

The silicone elastomer particles having the core-shell structure may have an average particle size of 0.1˜3 μm.

The curing agent may have a softening point of 100˜140° C. and a hydroxyl group equivalent of 100˜150.

The ratio of an epoxy group of the complex epoxy resin to a phenolic hydroxyl group of the curing agent may be 1:0.7˜1:1.3.

The curing accelerator may be an imidazole-based compound, and may specifically include one or more selected from the group consisting of 2-ethyl-4-methyl imidazole, 1-(2-cyanoethyl)-2-alkyl imidazole, 2-phenyl imidazole and mixtures thereof.

The inorganic filler may be surface treated with a silane coupling agent.

The inorganic filler may have an irregular outer shape.

Another aspect of the present invention provides a PCB, manufactured using the resin composition as above.

### BRIEF DESCRIPTION OF THE DRAWING

FIG. 1 schematically shows a core-shell structure of silicone elastomer particles used in the present invention.

### DESCRIPTION OF SPECIFIC EMBODIMENTS

Hereinafter, a detailed description will be given of the present invention with reference to the appended drawing.

The present invention is directed to a resin composition for an interlayer insulating layer of a PCB, which includes silicone elastomer particles having a core-shell structure, thus preventing the generation of delamination or cracking after thermal shock, resulting in high reliability. Also, the present invention is directed to a flame retardant resin composition, which has not only high peel strength but also superior thermal stability and mechanical strength, has a controllable degree of curing, and is not halogenated. Furthermore, when such a flame retardant composition is subjected to a conventional substrate manufacturing process, a PCB with the outer layer formed of the build-up insulating material can be obtained. In particular, flame retardancy and high peel strength can be manifested, and toughness of a final insulating material can be increased, ultimately enhancing thermal shock reliability.

According to an embodiment of the present invention, a resin composition includes a complex epoxy resin, a curing agent, a curing accelerator, and an inorganic filler.

The complex epoxy resin used in the present invention includes 20˜50 wt % of a bisphenol A epoxy resin prepared by dispersing silicone elastomer particles having a core-shell structure in a diglycidyl ether of bisphenol A (DGEBA) epoxy resin having an average epoxy resin equivalent of 200˜400, 20˜60 wt % of a cresol novolac epoxy resin having an average epoxy resin equivalent of 100˜300, and 20˜30 wt % of a phosphorus-based epoxy resin having an average epoxy resin equivalent of 400˜800.

Typically, silicone elastomer particles are not easy to disperse in a complex epoxy resin. Thus, in the present invention, the bisphenol A epoxy resin prepared by dispersing silicone elastomer particles in a bisphenol A epoxy resin which is the most generally used epoxy resin, in particular, a DGEBA epoxy resin, may be mixed with the novolac epoxy resin and the phosphorus-based flame retardant epoxy resin, thus obtaining uniform dispersibility and desired toughness.

An example of the DGEBA epoxy resin may include but is not limited to a compound represented by Formula 1 below.

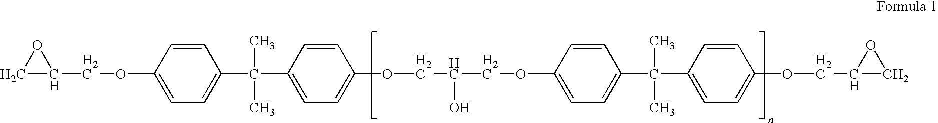

Present in the DGEBA epoxy resin of Formula 1, epoxy groups and secondary alcoholic hydroxyl groups have reactivity, and thus a curing reaction by the epoxy groups and/or the hydroxyl groups may occur. Also, because of a strong bonding force between benzene and isopropylidine, the free movement of the benzene ring is difficult. The ether bond of C—O—C in the molecular structure shows chemical resistance and plasticity, and a uniform arrangement of the hydrophilic hydroxyl groups and the hydrophobic hydrocarbons in the molecular structure results in a strong adhesive force. After the curing reaction, electrical properties are increased (electrical insulating properties, withstanding voltage, low dielectric constant). The above properties may vary depending on the degree of polymerization (n).

The DGEBA epoxy resin used in the present invention may have an average epoxy resin equivalent of 200˜400. If the average epoxy resin equivalent of the DGEBA epoxy resin is less than 200, desired properties are difficult to obtain. In contrast, if the average epoxy resin equivalent thereof exceeds 400, the resin is difficult to dissolve in a solvent and its melting point is drastically increased, thus making it difficult to control the resin.

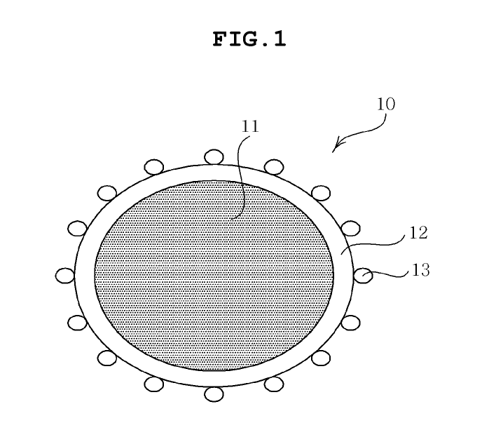

The silicone elastomer particles which are dispersed in the DGEBA epoxy resin have a structure of a core 11 and a shell 12, with reactive groups 13 thereon, as schematically shown in FIG. 1. The silicone elastomer particles 10 having a core-shell structure may form a chemical bond with the epoxy matrix. If a mechanical force is applied to the cured resin, it may be uniformly distributed in all directions in the silicone elastomer domain.

The silicone elastomer particles having the core-shell structure may have an average particle size of 0.1˜3 μm, in order to exhibit mechanical and dispersive properties.

The silicone elastomer particles which are dispersed in the DGEBA epoxy resin may be used in an amount of 20˜60 wt %. If the amount of the silicone elastomer particles is smaller than 20 wt %, improved toughness as desired in the present invention cannot be obtained. In contrast, if the amount thereof is larger than 60 wt %, the silicone elastomer particles are difficult to disperse.

The bisphenol A epoxy resin obtained by dispersing the silicone elastomer particles having the core-shell structure in the DGEBA epoxy resin may be contained in an amount of 20˜50 wt % in the complex epoxy resin. If the amount of the bisphenol A epoxy resin is smaller than 20 wt %, desired properties cannot be obtained. In contrast, if the amount thereof is larger than 50 wt %, the insulating material may become brittle, undesirably incurring cracking.

The above resin may be used in a state of being dissolved in a mixed solvent of 2-methoxy ethanol, methylethylketone (MEK) and dimethylformamide (DMF).

The cresol novolac epoxy resin which is a novolac type epoxy resin enables the formation of a cured product having high heat resistance and improves thermal stability of the resultant substrate. The cresol novolac epoxy resin may have an average epoxy resin equivalent of 100˜300, and may be contained in an amount of 20˜60 wt % in the complex epoxy resin.

If the average epoxy resin equivalent of the cresol novolac epoxy resin is less than 100, desired properties are difficult to obtain. In contrast, if the average epoxy resin equivalent thereof exceeds 300, the resin is difficult to dissolve in a solvent and its melting point is drastically increased, thus making it difficult to control the resin.

If the amount of the cresol novolac epoxy resin is smaller than 20 wt %, desired properties cannot be obtained. In contrast, if the amount thereof is greater than 60 wt %, electrical and mechanical properties are undesirably deteriorated.

The above resin may be used in a state of being dissolved in a mixed solvent of 2-methoxy ethanol and MEK, but the present invention is not particularly limited thereto.

The phosphorus-based epoxy resin has high flame retardancy and self-extinguishing properties. In the present invention, in order to impart the PCB with flame retardancy, the phosphorus-based epoxy resin is added, which does not contain a halogen, thereby obtaining an environmentally friendly flame retardant substrate.

The phosphorus-based epoxy resin may have an average epoxy resin equivalent of 400˜800. If the average epoxy resin equivalent of the phosphorus-based epoxy resin is less than 400, desired properties are difficult to obtain. In contrast, if the average epoxy resin equivalent thereof exceeds 800, the resin is difficult to dissolve in a solvent and its melting point is drastically increased, thus making it difficult to control the resin.

The phosphorus-based epoxy resin may be contained in an amount of 20˜30 wt % in the complex epoxy resin. If the amount of the phosphorus-based epoxy resin is smaller than 20 wt %, it is difficult to impart desired flame retardancy. In contrast, if the amount thereof is larger 30 wt %, electrical and mechanical properties are undesirably deteriorated.

The above resin may be used in a state of being dissolved in a mixed solvent of 2-methoxy ethanol, MEK and DMF.

The curing agent used in the present invention is a bisphenol A curing agent, thus improving curability and adhesive strength.

The curing agent may be used in an equivalent ratio of 0.3˜1.5 with respect to a total epoxy group equivalent of the complex epoxy resin.

To exhibit desired properties, particularly useful is a curing agent having a softening point of 100˜140° C. and a hydroxyl group equivalent of 100˜150. As such, a high hydroxyl group equivalent indicates that the bisphenol A curing agent is of a large molecular weight, thus increasing the softening point. Typically used in the present invention, the curing agent has a structure in which a predetermined number of repeating bisphenol units are linked between two hydroxyl groups. If the hydroxyl group equivalent is increased, the molecular weight of the curing agent for connecting the epoxy chains to each other is also increased, undesirably lowering the density of a final cured structure. Therefore, the curing agent having the hydroxyl group equivalent at an appropriate level as above may be used.

Also, the ratio of the epoxy group of the complex epoxy resin to the phenolic hydroxyl group of the curing agent falls in the range of from 1:0.7 to 1:1.3 in terms of exhibiting desired properties and reactivity.

In the present invention, the curing accelerator is exemplified by an imidazole-based compound, and includes but is not limited to at least one selected from among 2-ethyl-4-methyl imidazole, 1-(2-cyanoethyl)-2-alkyl imidazole, 2-phenyl imidazole and mixtures thereof.

The curing accelerator may be used in an amount of 0.1˜1 part by weight based on 100 parts by weight of the complex epoxy resin. If the amount of the curing accelerator is smaller than 0.1 parts by weight, a curing rate is remarkably decreased, and curing may not be performed. In contrast, if the amount thereof is larger than 1 part by weight, rapid curing may occur.

The inorganic filler used in the present invention is added to enhance properties such as mechanical strength in the cured product composed exclusively of the epoxy resin, and may include one or more selected from among graphite, carbon black, CaCO₃, and clay. The inorganic filler may be surface treated with a silane coupling agent, and may also have an irregular outer shape. So, while inorganic filler particles having irregular outer shapes are removed in the course of desmearing, a three-dimensional structure may result and may then be plated with a plating layer, thus forming mechanical anchoring, ultimately exhibiting high peel strength.

The inorganic filler may be used in an amount of 10˜30 parts by weight based on 100 parts by weight of the complex epoxy resin. If the amount of the inorganic filler is smaller than 10 parts by weight, it is difficult to improve desired mechanical properties. In contrast, if the amount thereof is greater than 30 parts by weight, desired peel strength cannot be obtained.

In addition, a flame retardant adjuvant may be added thus reducing the amount of the phosphorus-based flame retardant epoxy resin which is expensive. Such a flame retardant adjuvant may include a compound such as Al₂O₃ containing phosphorus, but the present invention is not limited thereto.

When the substrate is manufactured using the above resin composition, superior toughness and high peel strength can be obtained.

Furthermore, as the outermost layer of a substrate for a mobile phone is converted from a conventional prepreg type into a build-up type, peel strength which has been manifested through a conventional press process should be exhibited even after desmearing and plating using a build-up process. As such, because the resin composition according to the present invention has high peel strength, it can be very usefully applied to a build-up interlayer insulating layer.

A better understanding of the present invention may be obtained through the following example and comparative example which are set forth to illustrate, but are not to be construed as limiting the present invention.

### EXAMPLE 1

375 g of a bisphenol A epoxy resin obtained by dispersing 40 wt % of silicone elastomer particles having a core-shell structure with an average particle size of about 1 μm in a DGEBA epoxy resin having an average epoxy resin equivalent of 302, 750 g of a cresol novolac epoxy resin having an average epoxy resin equivalent of 206, 375 g of a flame retardant epoxy resin having an average epoxy resin equivalent of 590, and 992.76 g of 66.7 wt % bisphenol A novolac resin curing agent (solvent: 2-methoxy ethanol) were added to a mixed solvent of 239.54 g of MEK and 501 g of 2-methoxy ethanol and stirred at room temperature at 300 rpm. Thereafter, 442.85 g of an inorganic filler having an irregular shape with a size distribution of 2.53 μm was added thereto, and the mixture was stirred at 400 rpm for 3 hours. Finally, 0.25 parts by weight of 2-ethyl-4-methyl imidazole was added thereto, and the mixture was stirred for 1 hour, thus preparing an insulating material composition. The insulating material composition thus prepared was cast on a PET film, thus obtaining a roll-shaped product. The product was cut to a size of 405 mm×510 mm, and then subjected to a typical substrate manufacturing process, thus manufacturing a multilayered PCB. The multilayered PCB thus obtained was subjected to a solder dip test (260° C., 20 sec), thus checking whether external delamination occurred and whether internal cracking occurred after cutting of the PCB in a transverse cross-section direction. The results are shown in Table 1 below.

### COMPARATIVE EXAMPLE 1

14.99 g of 85 wt % bisphenol A epoxy resin (solvent: 2-methoxy ethanol), 73.33 g of 85 wt % cresol novolac epoxy resin (solvent: 2-methoxy ethanol), 10 g of a rubber-modified epoxy resin, 37.48 g of 85 wt % phosphorus-based flame retardant epoxy resin (solvent: 2-methoxy ethanol), and 56.50 g of 66.7 wt % aminotriazine-based novolac curing agent (solvent: 2-methoxy ethanol) were mixed and stirred at 90° C. for 1 hour at 300 rpm. Thereafter, 70.93 g of spherical silica having a size distribution of 0.6˜1.2 μm was added thereto, and the mixture was stirred at 400 rpm for 3 hours. The temperature was lowered to room temperature, after which 0.25 parts by weight of 2-ethyl-4-methyl imidazole was added thereto, and the mixture was stirred for 1 hour, thus preparing an insulating material composition. The insulating material composition thus prepared was cast on a PET film, thus obtaining a roll-shaped product. The product was cut to a size of 405 mm×510 mm, and then subjected to a typical substrate manufacturing process, thus manufacturing a multilayered PCB, which was then subjected to a solder dip test (260° C., 20 sec), thus checking whether external delamination occurred and whether internal cracking occurred after cutting of the PCB in a transverse cross-section direction. The results are shown in Table 1 below.

TABLE 1

| | Flame | | Solder Dip Test | |
|---|---|---|---|---|
| | Retardancy | Elongation | External | |
| | (UL 94) | (%) | Delamination | Internal Cracking |
| Ex. 1 | VO | 2.42 | No | No |
| C. Ex. 1 | VO | 1.57 | High Occurrence | Occurrence |

As is apparent from Table 1, the PCB manufactured using the resin composition according to the present invention has high elongation, and can prevent the generation of delamination or internal cracking in a solder dip test, and thus is evaluated to be highly reliable.

As described hereinbefore, the present invention provides a resin composition for a PCB and a PCB using the same. According to the present invention, the resin composition for a PCB can exhibit high toughness and can thus prevent delamination or cracking through efficient release of thermal stress in a reliability test, in particular, a thermal shock test. Furthermore, the resin composition can show peel strength at an appropriate level, and thus, upon use thereof as an interlayer insulating layer of a multilayered PCB, not only thermal stability and mechanical strength but also toughness can be increased remarkably, thereby increasing the reliability of the substrate.

Although the embodiments of the present invention have been disclosed for illustrative purposes, those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

What is claimed is:

1. A resin composition for a printed circuit board, comprising:
(a) a complex epoxy resin comprising 20˜50 wt % of a bisphenol A epoxy resin obtained by dispersing silicone elastomer particles having a core-shell structure in a diglycidyl ether of bisphenol A epoxy resin having an average epoxy resin equivalent of 200˜400, 20˜60 wt % of a cresol novolac epoxy resin having an average epoxy resin equivalent of 100˜300, and 20˜30 wt % of a phosphorus-based epoxy resin having an average epoxy resin equivalent of 400˜800;
(b) a bisphenol A curing agent used in an equivalent ratio of 0.3˜1.5 with respect to a total epoxy group equivalent of the complex epoxy resin;
(c) a curing accelerator used in an amount of 0.1˜1 part by weight based on 100 parts by weight of the complex epoxy resin; and
(d) an inorganic filler used in an amount of 10˜30 parts by weight based on 100 parts by weight of the complex epoxy resin.

2. The resin composition according to claim 1, wherein the silicone elastomer particles having the core-shell structure which are dispersed in the diglycidyl ether of bisphenol A epoxy resin are used in an amount of 20˜60 wt %.

3. The resin composition according to claim 1, wherein the silicone elastomer particles having the core-shell structure have an average particle size of 0.1˜3 μm.

4. The resin composition according to claim 1, wherein the curing agent has a softening point of 100˜140° C. and a hydroxyl group equivalent of 100˜150.

5. The resin composition according to claim 1, wherein a ratio of an epoxy group of the complex epoxy resin to a phenolic hydroxyl group of the curing agent is 1:0.7˜1:1.3.

6. The resin composition according to claim 1, wherein the curing accelerator is an imidazole-based compound.

7. The resin composition according to claim 6, wherein the curing accelerator is one or more selected from the group consisting of 2-ethyl-4-methyl imidazole, 1-(2-cyanoethyl)-2-alkyl imidazole, 2-phenyl imidazole and mixtures thereof.

8. The resin composition according to claim 1, wherein the inorganic filler is surface treated with a silane coupling agent.

9. The resin composition according to claim 1, wherein the inorganic filler has an irregular outer shape.

10. A printed circuit board, manufactured using the resin composition of claim 1.
